(19) United States
(12) Patent Application Publication
(10) Pub. No.: US 2025/0022907 A1
(43) Pub. Date: Jan. 16, 2025

(54) MANUFACTURING METHOD OF PHOTOELECTRIC CONVERSION PANEL, PHOTOELECTRIC CONVERSION PANEL, AND X-RAY IMAGING PANEL

(71) Applicant: Sharp Display Technology Corporation, Kameyama City (JP)

(72) Inventors: Rikiya TAKITA, Kameyama City (JP); Fumiki Nakano, Kameyama City (JP); Makoto Nakazawa, Kameyama City (JP); Hiroyuki Moriwaki, Kameyama City (JP)

(21) Appl. No.: 18/736,459

(22) Filed: Jun. 6, 2024

(30) Foreign Application Priority Data
Jul. 11, 2023 (JP) 2023-113616

(51) Int. Cl. H01L 27/146

(52) U.S. Cl. CPC H01L 27/14663; H01L 27/14612; H01L 27/14636; H01L 27/14683

(57) ABSTRACT

A manufacturing method of a photoelectric conversion panel includes forming a short ring, forming a plurality of data lines connected to a TFT and the short ring, forming a first conductive portion of a bias line connected to the photodiode in an upper layer above the photodiode, electrically blocking the short ring and the TFT from each other by cutting the plurality of data lines after the forming of the first conductive portion, and forming an inorganic insulating film in a blocking portion created by the plurality of data lines being cut.

### CROSS-REFERENCE TO RELATED APPLICATIONS

This application claims the benefit of priority to Japanese Patent Application Number 2023-113616 filed on Jul. 11, 2023. The entire contents of the above-identified application are hereby incorporated by reference.

### BACKGROUND

### Technical Field

The disclosure relates to a manufacturing method of a photoelectric conversion panel, a photoelectric conversion panel, and an X-ray imaging panel.

JP 7-99344 A discloses a manufacturing method of a semiconductor light-emitting device. This manufacturing method includes forming a plurality of electrodes on a substrate and, before dividing the substrate, forming a short circuit wiring line connected to all of the plurality of electrodes on the substrate with the short circuit wiring line straddling a cutting line. Subsequently, the substrate is divided along the cutting line.

JP 2011-164231 A discloses an active matrix substrate provided with a short ring. This active matrix substrate includes a display circuit unit including a plurality of gate wiring lines, a plurality of source wiring lines, and a transistor, a static electricity protection element, a short ring, a fuse, and a heater. The fuse is disposed between the short ring and the display circuit unit. The short ring is connected to the display circuit unit via the fuse and the static electricity protection element and short-circuits the display circuit unit in a state before the fuse is cut. Then, the fuse is heated by the heater, and subsequently, a current is passed through the fuse to cut the fuse. As a result, the display circuit unit is blocked from the short ring.

### SUMMARY

According to the manufacturing method of the semiconductor light-emitting device disclosed in JP 7-99344 A described above, in a process before the substrate is divided, static electricity can be dispersed by the short circuit wiring line. However, after the substrate is divided along the cutting line, the short circuit wiring line is exposed at an outer end surface of the substrate. This is problematic in that static electricity readily enters through the exposed short circuit wiring line.

In the manufacturing method of the active matrix substrate described in JP 2011-164231 A, after the fuse is heated by the heater, a current is passed through the fuse to cut the fuse, thereby blocking the short ring from the display circuit unit. As a result, unlike JP 7-99344 A described above in which the substrate is divided, the short ring is not exposed at the outer end surface of the substrate.

However, in the active matrix substrate described in JP 2011-164231 A, it is necessary to provide a fuse and a heater to the active matrix substrate in order to electrically block the short ring from the display circuit unit (transistor). This increases the number of components of the active matrix substrate (panel). Further, this necessitates a manufacturing process of arranging the fuse and the heater on the active matrix substrate and a manufacturing process of supplying a current to each of the fuse and the heater.

The disclosure has been made to solve such problems as described above, and an object of the disclosure is to provide a manufacturing method of a photoelectric conversion panel, a photoelectric conversion panel, and an X-ray imaging panel that facilitate a reduction in the number of components and a reduction in the number of manufacturing processes while preventing a wiring line from being exposed.

To solve the problems described above, a manufacturing method of a photoelectric conversion panel according to a first aspect of the disclosure includes forming a transistor in a pixel region on a substrate, forming a photodiode connected to the transistor in the pixel region, forming a short ring surrounding the pixel region in a plan view, forming a plurality of wiring lines short-circuited by the short ring and connected to the transistor or the photodiode and the short ring, forming a bias line connected to the photodiode in an upper layer above the photodiode, electrically blocking the short ring and the transistor or the photodiode from each other by cutting the plurality of wiring lines after the forming of the bias line, and forming a first insulating film in a recessed portion created by the plurality of wiring lines being cut.

A photoelectric conversion panel according to a second aspect includes a transistor formed in a pixel region on a substrate, a photodiode formed in the pixel region and connected to the transistor, a ring-shaped wiring line surrounding the pixel region in a plan view, a wiring line portion including a first conductive portion connected to the transistor or the photodiode and a second conductive portion connected to the ring-shaped wiring line, the first conductive portion and the second conductive portion being electrically blocked from each other, a bias line formed in an upper layer above the photodiode and connected to the photodiode, and a first insulating film formed in an upper layer above the bias line with at least a portion being formed between the first conductive portion and the second conductive portion, the first insulating film being configured to insulate the first conductive portion and the second conductive portion.

An X-ray imaging panel according to a third aspect includes a transistor formed in a pixel region on a substrate, a photodiode formed in the pixel region and connected to the transistor, a ring-shaped wiring line surrounding the pixel region in a plan view, a wiring line portion including a first portion connected to the transistor or the photodiode and a second portion connected to the ring-shaped wiring line, the first portion and the second portion being electrically blocked from each other, a bias line formed in an upper layer above the photodiode and connected to the photodiode, a first insulating film formed in an upper layer above the bias line with at least a portion being formed between the first portion and the second portion, the first insulating film being configured to insulate the first portion and the second portion, and a scintillator covering the pixel region.

According to the configurations described above, it is possible to prevent, by the first insulating film, the plurality of wiring lines from being exposed after the plurality of wiring lines are cut. Further, it is possible to electrically block the short ring and the transistor or the photodiode from each other without arranging components (for example, a fuse and a heater) for cutting the wiring lines in the photoelectric conversion panel (X-ray imaging panel). As a result, the number of components of the photoelectric conversion panel (X-ray imaging panel) can be reduced. Further, the arrangement of components for cutting the wiring lines is not required, making it possible to reduce the number of manufacturing processes of the photoelectric conversion panel.

### BRIEF DESCRIPTION OF DRAWINGS

The disclosure will be described with reference to the accompanying drawings, wherein like numbers reference like elements.

FIG. 1 is a schematic view illustrating an X-ray imaging device 100 provided with an X-ray imaging panel 10 including a photoelectric conversion panel 1.

FIG. 2 is a schematic plan view illustrating a schematic configuration of the photoelectric conversion panel 1.

FIG. 3 is a cross-sectional view illustrating a configuration inside a pixel region R1 of the photoelectric conversion panel 1.

FIG. 4 is a cross-sectional view (1) illustrating a boundary portion between the pixel region R1 and a frame region R2.

FIG. 5 is a cross-sectional view (2) illustrating a boundary portion between the pixel region R1 and the frame region R2.

FIG. 6 is a cross-sectional view (3) illustrating a boundary portion between the pixel region R1 and the frame region R2.

FIG. 7 is a cross-sectional view illustrating a configuration inside the frame region R2 of the photoelectric conversion panel 1.

FIG. 8 is a flowchart for explaining a manufacturing process of the photoelectric conversion panel 1 and the X-ray imaging panel 10.

FIG. 9 is a cross-sectional view (1) for explaining a manufacturing process of the photoelectric conversion panel 1 and the X-ray imaging panel 10.

FIG. 10 is a cross-sectional view (2) for explaining a manufacturing process of the photoelectric conversion panel 1 and the X-ray imaging panel 10.

FIG. 11 is a cross-sectional view (3) for explaining a manufacturing process of the photoelectric conversion panel 1 and the X-ray imaging panel 10.

FIG. 12 is a cross-sectional view (4) for explaining a manufacturing process of the photoelectric conversion panel 1 and the X-ray imaging panel 10.

FIG. 13 is a cross-sectional view (5) for explaining a manufacturing process of the photoelectric conversion panel 1 and the X-ray imaging panel 10.

FIG. 14 is a cross-sectional view (6) for explaining a manufacturing process of the photoelectric conversion panel 1 and the X-ray imaging panel 10.

FIG. 15 is a cross-sectional view (7) for explaining a manufacturing process of the photoelectric conversion panel 1 and the X-ray imaging panel 10.

### DESCRIPTION OF EMBODIMENTS

Embodiments of the disclosure will be described below with reference to the drawings. Note that the disclosure is not limited to the following embodiments, and appropriate design changes can be made within a scope that satisfies the configuration of the disclosure. In the description below, the same reference signs are used in common among the different drawings for portions having the same or similar functions, and repeated description thereof will be omitted. Further, the configurations described in the embodiments and the modified examples may be combined or modified as appropriate within a range that does not depart from the gist of the disclosure. For ease of explanation, in the drawings referenced below, the configuration is simplified or schematically illustrated, or a portion of the components is omitted. Further, dimensional ratios between components illustrated in the drawings are not necessarily indicative of actual dimensional ratios.

### Configuration of X-Ray Imaging Device 100

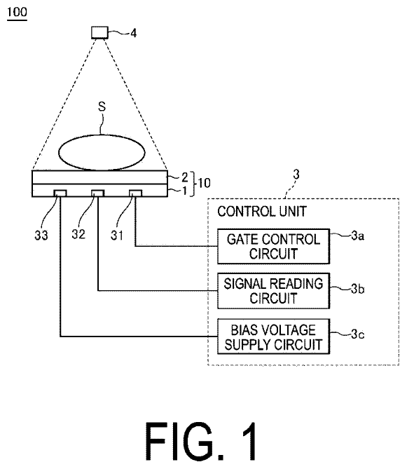

FIG. 1 is a schematic view illustrating an X-ray imaging device 100 provided with an X-ray imaging panel 10 including a photoelectric conversion panel 1 according to the present embodiment. The X-ray imaging device 100 is provided with the X-ray imaging panel 10 including the photoelectric conversion panel 1 and a scintillator 2, a control unit 3, and an X-ray source 4.

As illustrated in FIG. 1, the control unit 3 includes a gate control circuit 3a, a signal reading circuit 3b, and a bias voltage supply circuit 3c. The gate control circuit 3a is connected to a gate terminal 31 of the photoelectric conversion panel 1. The signal reading circuit 3b is connected to a data terminal 32. The bias voltage supply circuit 3c is connected to a bias terminal 33.

The X-ray source 4 irradiates a subject S with X-rays. X-rays passing through the subject S are converted into fluorescence (hereinafter, referred to as “scintillation light”) in the scintillator 2 disposed at an upper portion of the photoelectric conversion panel 1. The X-ray imaging device 100 generates an X-ray image by imaging the scintillation light with the X-ray imaging panel 10.

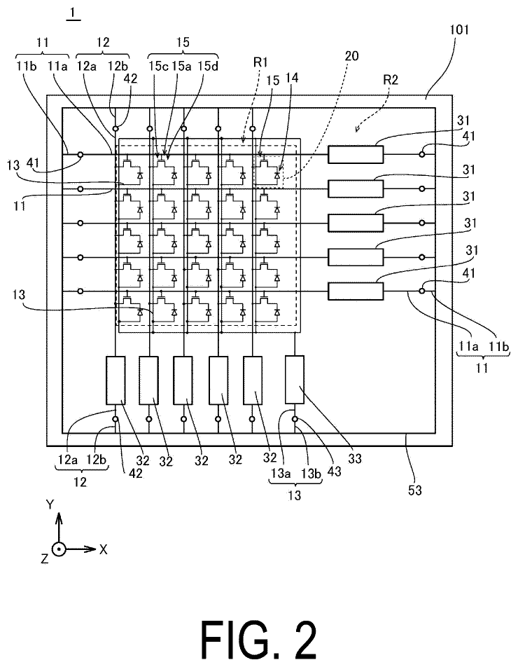

FIG. 2 is a schematic plan view illustrating a schematic configuration of the photoelectric conversion panel 1. A plurality of the gate terminals 31, a plurality of the data terminals 32, the bias terminal 33, a plurality of photodiodes 14, and a plurality of thin film transistors (TFTs) 15 are formed on a substrate 101 of the photoelectric conversion panel 1. A plurality of gate lines 11, a plurality of data lines 12, a bias line 13, and a short ring 53 are formed on the substrate 101 of the photoelectric conversion panel 1.

The plurality of gate lines 11 include first conductive portions 11a connecting gate electrodes 15a of the TFTs 15 and the gate terminals 31, and second conductive portions 11b connected to the short ring 53. The first conductive portion 11a and the second conductive portion 11b are electrically blocked from each other at a blocking portion 41. The plurality of data lines 12 include first conductive portions 12a connecting source electrodes 15c of the TFTs 15 and the data terminals 32, and second conductive portions 12b connected to the short ring 53. The first conductive portion 12a and the second conductive portion 12b are electrically blocked from each other at a blocking portion 42. The bias line 13 includes a first conductive portion 13a connecting the photodiodes 14 and the bias terminal 33, and a second conductive portion 13b connected to the short ring 53. The first conductive portion 13a and the second conductive portion 13b are electrically blocked from each other at a blocking portion 43.

As illustrated in FIG. 2, the photoelectric conversion panel 1 is provided with a pixel region R1 (active region) and a frame region R2. The pixel region R1 has, for example, a rectangular shape in a plan view. The pixel region R1 is a region in which a plurality of pixels 20 are formed. The pixels 20 are the regions defined by the gate lines 11 and the data lines 12. Each of the first conductive portions 11a, 12a, and 13a is formed on the substrate 101 from the pixel region R1 to the frame region R2.

As illustrated in FIG. 2, in the pixel region R1, the plurality of gate lines 11 and the plurality of data lines 12 are formed intersecting one another. Thus, the plurality of pixels 20 are formed in a matrix in a plan view. The photoelectric conversion panel 1 includes an active matrix substrate. The bias line 13 is formed, for example, along the data line 12. Each of the pixels 20 is provided with the photodiode 14 and the TFT 15.

As illustrated in FIG. 2, the frame region R2 is provided on the substrate 101 outside the pixel region R1. In the frame region R2, the gate terminals 31, the data terminals 32, the bias terminal 33, and the short ring 53 are disposed. The short ring 53 is formed in a rectangular frame-like shape surrounding the pixel region R1. The short ring 53 is a ring-shaped wiring line. The short ring 53 is formed on an outer side of the substrate 101 (at a position close to an outer end portion), outward of the gate terminals 31, the data terminals 32, and the bias terminal 33. In the frame region R2, the plurality of gate terminals 31 are disposed side by side in a Y direction. Also, in the frame region R2, the plurality of data terminals 32 and the bias terminal 33 are disposed side by side in an X direction. The plurality of gate terminals 31 transmit gate signals from the gate control circuit 3a to the gate lines 11. The plurality of data terminals 32 apply a reading voltage from the signal reading circuit 3b to the data lines 12. The plurality of data terminals 32 acquire data signals from the photodiodes 14 via the data lines 12 and the TFTs 15 and transmit the data signals to the signal reading circuit 3b. The bias terminal 33 supplies a bias voltage from the bias voltage supply circuit 3c to the bias line 13.

The blocking portions 41 are formed between the gate terminals 31 and the short ring 53 in a plan view in the frame region R2. The blocking portions 42 are formed between the data terminals 32 and the short ring 53 in a plan view in the frame region R2. The blocking portion 43 is formed between the bias terminal 33 and the short ring 53 in a plan view in the frame region R2.

The control unit 3 illustrated in FIG. 1 generates an X-ray image on the basis of data signals obtained by the signal reading circuit 3b when X-rays are emitted from the X-ray source 4. The photodiodes 14 convert the scintillation light into a charge based on the amount of scintillation light obtained by the scintillator converting the X-rays that pass through the subject S when a bias voltage is applied from the bias line 13 and transmit the signals (data signals) corresponding to the charge to the TFTs 15. Then, the control unit 3 causes gate signals to be sequentially and selectively supplied from the gate control circuit 3a to the gate lines 11. The TFTs 15 that are supplied with a gate signal are put in an on state. When a reading voltage is applied to the data line 12 via the signal reading circuit 3b and the TFT 15 is put in the on state, a signal (data signal) corresponding to the charge converted at the photodiode 14 is applied to the reading voltage. Then, the signal reading circuit 3b obtains a data signal. The control unit 3 generates an X-ray image on the basis of the data signals of each pixel 20 in the pixel region R1.

### Detailed Configuration of Photoelectric Conversion Panel 1

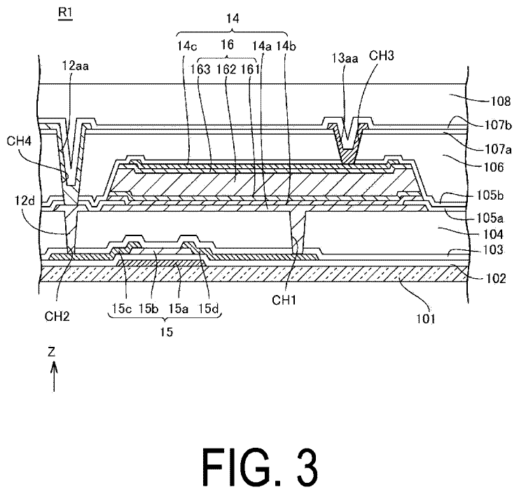

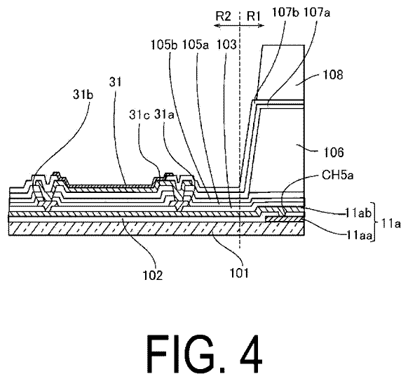

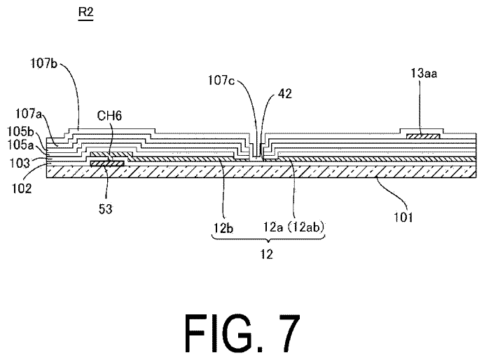

The configuration of the photoelectric conversion panel 1 will now be described in detail with reference to FIG. 3 to FIG. 7. FIG. 3 is a cross-sectional view illustrating the configuration inside the pixel region R1 of the photoelectric conversion panel 1. FIG. 4 to FIG. 6 are cross-sectional views illustrating boundary portions between the pixel region R1 and the frame region R2. FIG. 7 is a cross-sectional view illustrating the configuration inside the frame region R2 of the photoelectric conversion panel 1.

### Gate Lines, Data Lines, and Bias Line

As illustrated in FIG. 4 to FIG. 7, in the frame region R2, the first conductive portions 11a, 12a, and 13a are formed in the same layer as the layer in which the source electrodes 15c and drain electrodes 15d are formed (refer to FIG. 3). As illustrated in FIG. 7, the second conductive portions 11b, 12b, and 13b are each formed in the frame region R2 on the substrate 101. The second conductive portions 11b, 12b, and 13b are formed in the same layer as the layer in which the source electrodes 15c and the drain electrodes 15d are formed (refer to FIG. 3).

Here, a portion of the first conductive portion 11a formed in the same layer as the layer in which the gate electrodes 15a are formed is referred to as a first conductive portion 11aa, and a portion formed in the same layer as the layer in which the source electrodes 15c and the drain electrodes 15d are formed is referred to as a first conductive portion 11ab. Further, a portion of the first conductive portion 12a formed in an upper layer above the layer in which the photodiode 14 is formed is referred to as a first conductive portion 12aa, and a portion formed in the same layer as the layer in which the source electrodes 15c and the drain electrodes 15d are formed is referred to as a first conductive portion 12ab.

### Configuration Inside Pixel Region R1

As illustrated in FIG. 3, the TFT 15 includes the gate electrode 15a connected to the gate line 11 (refer to FIG. 2), a semiconductor active layer 15b, the source electrode 15c connected to the data line 12, and the drain electrode 15d connected to the photodiode 14. The photodiode 14 is formed in an upper layer above the layer in which the TFT 15 is formed. Also, the photodiode 14 includes a photoelectric conversion layer 16, a cathode 14b, and an anode 14c. The photoelectric conversion layer 16 is provided between the cathode 14b and the anode 14c. Also, the drain electrode 15d and the cathode 14b are connected via a cathode connection electrode 14a provided in a contact hole CH1.

The photoelectric conversion panel 1 also includes a connection electrode 12d that connects the source electrode 15c and the data line 12. A portion of the connection electrode 12d is disposed in a contact hole CH2 and is connected to the first conductive portion 12aa of the data line 12 via the contact hole CH2. A portion of the first conductive portion 13aa of the bias line 13 is formed inside a contact hole CH3. In the pixel region R1, the bias line 13 is formed in an upper layer above the layer in which the photodiode 14 is formed.

Also, as illustrated in FIG. 3, the gate electrode 15a is formed on the substrate 101. The substrate 101 is a glass substrate with insulating properties, for example. The gate electrode 15a is formed as a layered film containing, for example, tungsten (W) and tantalum nitride (TaN) as materials. A gate insulating film 102 is formed covering the gate electrode 15a. The gate insulating film 102 has a layered configuration including, for example, an insulating film made of silicon oxide (SiO₂) as an upper layer and an insulating film made of silicon nitride (SiNₓ) as a lower layer. The first conductive portion 11aa of the gate line 11 illustrated in FIG. 4 is made of the same material as the gate electrode 15a.

The semiconductor active layer 15b and the source electrode 15c and the drain electrode 15d connected to the semiconductor active layer 15b are formed above the gate electrode 15a with the gate insulating film 102 formed therebetween. The semiconductor active layer 15b includes an oxide semiconductor. The oxide semiconductor is an amorphous oxide semiconductor containing indium (In), gallium (Ga), and zinc (Zn) in a predetermined ratio, for example. With this configuration, the off-leak current of the thin film transistor 15 can be reduced more than when amorphous silicon (a-Si) is used. When the off-leak current of the thin film transistor 15 is small, a sensor panel with high sensitivity can be obtained, and the photoelectric conversion panel 1 with low exposure can be obtained. Note that the semiconductor active layer 15b is not limited to this configuration, and amorphous oxide semiconductors such as InGaO₃(ZnO)₅, magnesium zinc oxide (MgₓZn₁₋ₓO), cadmium zinc oxide (CdₓZn₁₋ₓO), cadmium oxide (CdO), InSnZnO (containing indium (In), tin (Sn), and zinc (Zn)), and In (indium)-Al (aluminum)-Zn (zinc)-O (oxygen)-based amorphous oxide semiconductors may be used. “Amorphous” materials and “crystalline” materials (including polycrystalline, microcrystalline, and c-axis aligned materials) can also be used as the oxide semiconductor.

The source electrode 15c and the drain electrode 15d are disposed in contact with part of the semiconductor active layer 15b on the gate insulating film 102. The source electrode 15c and the drain electrode 15d are formed in the same layer. The source electrode 15c and the drain electrode 15d have a triple-layer structure obtained by layering two metal films made of titanium (Ti) with a metal film made of aluminum (Al) interposed therebetween, for example.

As illustrated in FIG. 3, a protection film 103 is provided covering the source electrode 15c and the drain electrode 15d above the gate insulating film 102. The protection film 103 is made of silicon oxide (SiO₂), for example. A flattening film 104 is provided in an upper layer above the protection film 103. In other words, the flattening film 104 levels an upper portion of the thin film transistor 15. The flattening film 104 is formed of an organic insulating film containing a resin material (organic material).

The cathode connection electrode 14a is formed in an upper layer above the flattening film 104. The connection electrode 12d is formed in the same layer as the cathode connection electrode 14a, in an upper layer above the flattening film 104. The cathode connection electrode 14a is formed inside the contact hole CH1 and connects the drain electrode 15d and the cathode 14b. The connection electrode 12d is formed inside the contact hole CH2 and connects the source electrode 15c and the first conductive portion 12a. The cathode connection electrode 14a and the connection electrode 12d have a triple-layer structure obtained by layering two metal films made of titanium (Ti) with a metal film made of aluminum (Al) interposed therebetween, for example. Here, the cathode connection electrode 14a and the connection electrode 12d contain aluminum and, since aluminum has a lower electrical resistance value than ITO, the cathode connection electrode 14a and the connection electrode 12d have low electrical resistance values.

An inorganic insulating film 105a is formed in an upper layer above the cathode connection electrode 14a and the connection electrode 12d. A contact hole CH4 is provided above the connection electrode 12d in the inorganic insulating film 105a, and part of the first conductive portion 12a is provided inside the contact hole CH4. The inorganic insulating film 105a is made of silicon nitride (SiNₓ) or silicon dioxide (SiO₂), for example.

The cathode 14b of the photodiode 14 is formed covering part of the inorganic insulating film 105a in an upper layer above the cathode connection electrode 14a. Also, the cathode 14b and the cathode connection electrode 14a are in contact with one another. The cathode 14b is made of titanium (Ti), for example.

The photoelectric conversion layer 16 is formed in an upper layer above the cathode 14b. The photoelectric conversion layer 16 includes an n-type amorphous semiconductor layer 161, an intrinsic amorphous semiconductor layer 162, and a p-type amorphous semiconductor layer 163 sequentially layered. The n-type amorphous semiconductor layer 161 is made of amorphous silicon doped with n-type impurities (for example, phosphorus). The intrinsic amorphous semiconductor layer 162 is made of intrinsic amorphous silicon. The intrinsic amorphous semiconductor layer 162 is formed in contact with the n-type amorphous semiconductor layer 161. The p-type amorphous semiconductor layer 163 is made of amorphous silicon doped with p-type impurities (for example, boron). The p-type amorphous semiconductor layer 163 is formed in contact with the intrinsic amorphous semiconductor layer 162. The anode 14c is formed above the photoelectric conversion layer 16. For example, the anode 14c is made of indium tin oxide (ITO).

An inorganic insulating film 105b is formed covering at least part of the photodiode 14 and the inorganic insulating film 105a. The contact hole CH3 where part of the bias line 13 is provided is formed in the inorganic insulating film 105b. Also, the inorganic insulating film 105b covers part of an upper surface of the photodiode 14, and a side surface of the photodiode 14. The contact holes CH3 and CH4 are formed in the inorganic insulating film 105b. The inorganic insulating film 105b is formed as an inorganic insulating film and is made of silicon nitride (SiNₓ) or silicon dioxide (SiO₂), for example.

A flattening film 106 is formed in an upper layer above the photodiode 14, covering the inorganic insulating film 105b. Also, the flattening film 106 covers the photodiode 14 and levels a step portion formed by the photodiode 14. The flattening film 106 is made of the same material (organic insulating film) as the flattening film 104, for example. The contact holes CH3 and CH4 are formed in the flattening film 106.

An inorganic insulating film 107a is formed in an upper layer above the flattening film 106. The contact holes CH3 and CH4 are formed in the inorganic insulating film 107a. The first conductive portion 12aa of the data line 12 and the first conductive portion 13aa of the bias line 13 are formed in an upper layer above the inorganic insulating film 107a.

The first conductive portion 12aa and the connection electrode 12d are connected inside the contact hole CH4. Also, the first conductive portion 13aa and the anode 14c of the photodiode 14 are connected inside the contact hole CH3. The first conductive portion 12a and the first conductive portion 13aa include a layer having a triple-layer structure obtained by layering two metal films made of titanium (Ti) with a metal film made of aluminum (Al) interposed therebetween, and a layer made of ITO, for example.

An inorganic insulating film 107b is formed covering the inorganic insulating film 107a, the first conductive portion 12a, and the bias line 13. Also, the inorganic insulating films 107a and 107b are passivation films (protection films). The inorganic insulating films 107a and 107b are made of silicon nitride (SiNₓ) or silicon dioxide (SiO₂), for example.

A flattening film 108 is formed covering the inorganic insulating film 107b. The flattening film 108 levels the portion above the first conductive portion 12aa and the first conductive portion 13aa. Also, the flattening film 108 is made of the same material (organic insulating film) as the flattening film 104, for example.

### Configuration of Frame Region R2

As illustrated in FIG. 4, the first conductive portion 11aa and the first conductive portion 11ab of the gate line 11 are connected to each other via a contact hole CH5a formed in the gate insulating film 102. The gate terminal 31 is disposed above the first conductive portion 11ab. The photoelectric conversion panel 1 includes terminal connection electrodes 31a, 31b, and 31c that connect the gate terminal 31 and the first conductive portion 11ab. The terminal connection electrodes 31a and 31b are formed in the same layer as the layer in which the cathode connection electrode 14a is formed. The terminal connection electrodes 31a and 31b are made of the same material as the cathode connection electrode 14a. The terminal connection electrode 31c is formed in the same layer as the layer in which the first conductive portion 13aa of the bias line 13 is formed. The terminal connection electrode 31c is made of the same material as the first conductive portion 13aa of the bias line 13. The first conductive portion 11ab is made of the same material as the source electrode 15c and the drain electrode 15d. The gate terminal 31 is made of ITO, for example.

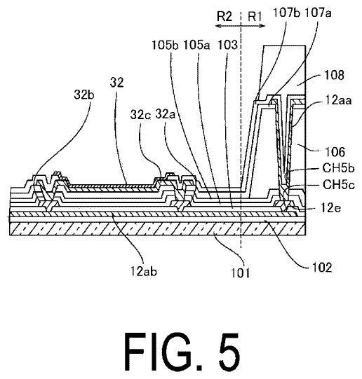

As illustrated in FIG. 5, the first conductive portion 12aa and the first conductive portion 12ab of the data line 12 are connected via a connection electrode 12e. The first conductive portion 12aa and the connection electrode 12e are connected to each other via a contact hole CH5b formed in the flattening film 106. The connection electrode 12e and the first conductive portion 12ab are connected via a contact hole CH5c formed in the protection film 103. The data terminal 32 is disposed above the first conductive portion 12ab. The photoelectric conversion panel 1 includes terminal connection electrodes 32a, 32b, and 32c that connect the data terminal 32 and the first conductive portion 12ab. The terminal connection electrodes 32a and 32b are formed in the same layer as the layer in which the cathode connection electrode 14a is formed. The terminal connection electrodes 32a and 32b are made of the same material as the cathode connection electrode 14a. The terminal connection electrode 32c is formed in the same layer as the layer in which the first conductive portion 13aa of the bias line 13 is formed. The terminal connection electrode 32c is made of the same material as the first conductive portion 13aa of the bias line 13. The first conductive portion 12ab is made of the same material as the source electrode 15c and the drain electrode 15d. The data terminal 32 is made of ITO, for example.

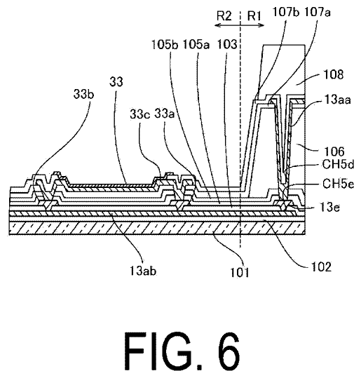

As illustrated in FIG. 6, the first conductive portion 13aa and the first conductive portion 13ab of the bias line 13 are connected via a connection electrode 13e. The first conductive portion 13aa and the connection electrode 13e are connected to each other via a contact hole CH5d formed in the flattening film 106. The connection electrode 13e and the first conductive portion 13ab are connected via a contact hole CH5e formed in the protection film 103. The bias terminal 33 is disposed above the first conductive portion 13ab. The photoelectric conversion panel 1 includes terminal connection electrodes 33a, 33b, and 33c that connect the bias terminal 33 and the first conductive portion 13ab. The terminal connection electrodes 33a and 33b are formed in the same layer as the layer in which the cathode connection electrode 14a is formed. The terminal connection electrodes 33a and 33b are made of the same material as the cathode connection electrode 14a. The terminal connection electrode 33c is formed in the same layer as the layer in which the first conductive portion 13aa of the bias line 13 is formed. The terminal connection electrode 33c is made of the same material as the first conductive portion 13aa of the bias line 13. The first conductive portion 13ab is made of the same material as the source electrode 15c and the drain electrode 15d. The bias terminal 33 is made of ITO, for example.

As illustrated in FIG. 7, the short ring 53 is formed on the substrate 101 in the frame region R2. The short ring 53 is formed in the same layer as the layer in which the gate electrode 15a is formed. The short ring 53 is made of the same material as the gate electrode 15a. In the frame region R2, a contact hole CH6 is formed in the gate insulating film 102. The contact hole CH6 is formed above the short ring 53. The second conductive portion 12b of the data line 12 is disposed in the contact hole CH6. The short ring 53 is connected to the second conductive portion 12b in the contact hole CH6.

In the data line 12, the first conductive portion 12a (first conductive portion 12ab) and the second conductive portion 12b are separated from each other by the blocking portion 42 in the frame region R2. Thus, the first conductive portion 12a and the second conductive portion 12b are electrically blocked from each other. The blocking portion 42 is formed in a recessed shape recessed toward the substrate 101. A portion 107c of the inorganic insulating film 107b is disposed in the blocking portion 42. Note that a portion of the frame region R2 where the gate line 11 and the blocking portion 41 are disposed and a portion of the frame region R2 where the bias line 13 and the blocking portion 43 are disposed have the same configuration as a portion of the frame region R2 illustrated in FIG. 7 where the data line 12 and the blocking portion 42 are disposed. Therefore, the description of the portion of the frame region R2 where the gate line 11 and the blocking portion 41 are disposed and the portion of the frame region R2 where the bias line 13 and the blocking portion 43 are disposed will be omitted.

According to the configuration described above, the first conductive portion 12a and the second conductive portion 12b are covered with the inorganic insulating film 107b, making it possible to prevent the data line 12 from being exposed. The short ring 53 and the TFT 15 or the photodiode 14 can be electrically blocked from each other without arranging components (for example, a fuse and a heater) for disconnecting the first conductive portion 12a and the second conductive portion 12b in the photoelectric conversion panel 1. As a result, the number of components of the photoelectric conversion panel 1 can be reduced.

### Manufacturing Method of Photoelectric Conversion Panel 1

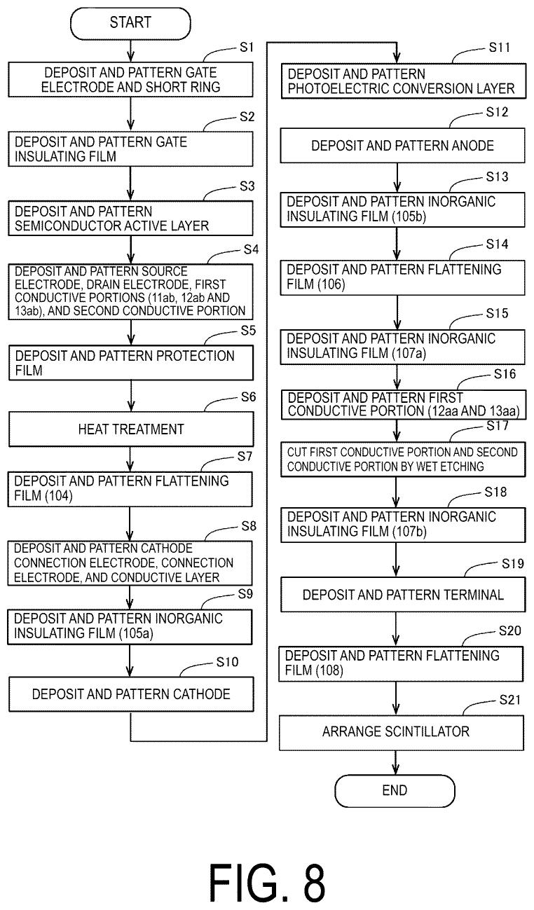

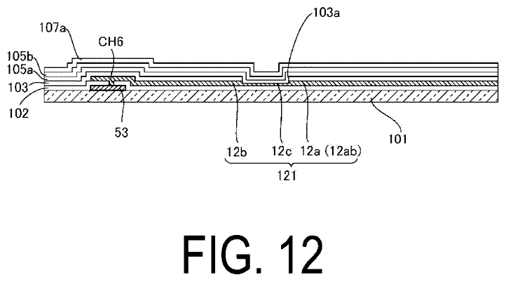

Next, a manufacturing method of the photoelectric conversion panel 1 according to the present embodiment will be described with reference to FIG. 3 to FIG. 14. FIG. 8 is a flowchart for explaining a manufacturing process of the photoelectric conversion panel 1.

Of the manufacturing method relating to the frame region R2 of the photoelectric conversion panel 1, the manufacturing method of the portion where the data line 12 and the blocking portion 42 are disposed will be described below. A portion of the frame region R2 where the gate line 11 and the blocking portion 41 are disposed and a portion of the frame region R2 where the bias line 13 and the blocking portion 43 are disposed are manufactured using the same method as that of the portion of the frame region R2 where the data line 12 and the blocking portion 42 are disposed, and therefore description thereof will be omitted.

As illustrated in FIG. 8, in step S1, in the pixel region R1, the gate electrode 15a (refer to FIG. 3) and the first conductive portion 11aa (refer to FIG. 4) of the gate line 11 are deposited on the substrate 101 and patterned. Also, in this step S1, as illustrated in FIG. 6, in the frame region R2, the short ring 53 is deposited on the substrate 101 and patterned.

In step S2, the gate insulating film 102 is deposited, covering the gate electrode 15a, the first conductive portion 11aa, and the short ring 53, and patterned. During the patterning in this step S2, the contact hole CH6 is formed in the frame region R2. In step S3, in the pixel region R1, the semiconductor active layer 15b (refer to FIG. 3) is deposited on the gate insulating film 102 and patterned.

In step S4, in the pixel region R1, the source electrode 15c and the drain electrode 15d are deposited on the gate insulating film 102 and patterned. In this manner, the thin film transistor 15 is formed. Also, in step S4, as illustrated in FIG. 6, in the frame region R2, the first conductive portion 12ab, the second conductive portion 12b, and the third conductive portion 12c, which constitute a data line 121, are formed on the gate insulating film 102. The third conductive portion 12c connects the first conductive portion 12ab and the second conductive portion 12b. Note that a data line in a state before the first conductive portion 12ab and the second conductive portion 12b are blocked from each other is referred to as the “data line 121,” and a data line in a state after the first conductive portion 12ab and the second conductive portion 12b are blocked from each other is referred to as the “data line 12.”

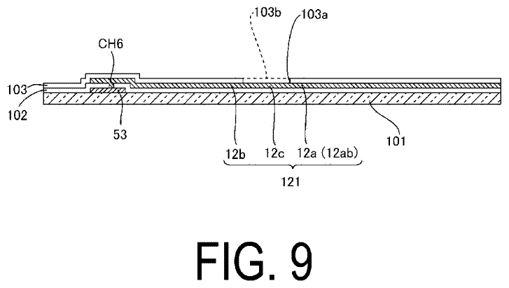

As illustrated in FIG. 9, part of the first conductive portion 12ab is disposed in the contact hole CH6. The short ring 53 is connected to the data line 121. Further, the short ring 53 is connected to the plurality of data lines 121. The short ring 53 is connected to the plurality of TFTs 15 and the plurality of data terminals 32 via the plurality of data lines 121. As a result, the short ring 53 short-circuits the plurality of data lines 121 and short-circuits the plurality of TFTs 15 and the plurality of data terminals 32. Accordingly, even when the photodiode 14 or the TFT 15 in the pixel region R1 is charged during the manufacturing process of the photoelectric conversion panel 1, static electricity can be diffused by the short ring 53 to protect the TFT 15 and the photodiode 14 against static electricity.

In step S5, as illustrated in FIG. 3, in the pixel region R1, the protection film 103 is deposited on the gate insulating film 102, covering the source electrode 15c and the drain electrode 15d, and patterned. Also, as illustrated in FIG. 9, in the frame region R2, the protection film 103 is deposited on the gate insulating film 102, covering the data line 121, and patterned. As illustrated in FIG. 9, during this patterning, a portion 103b of the protection film 103 overlapping a portion (third conductive portion 12c) of the data line 121 to be cut in a plan view is removed to expose the third conductive portion 12c.

In step S6, heat treatment (annealing treatment) is performed on the exposed third conductive portion 12c of the data line 121. As a result, the SiO₂ (silicon dioxide) of the protection film 103 and the aluminum of the third conductive portion 12c are bonded to each other, and the third conductive portion 12c is changed to a state containing an aluminum-silicon alloy. As a result, in the frame region R2, when dry etching is performed on the cathode connection electrode 14a and when dry etching is performed on the bias line 13 (first conductive portion 13aa), it is possible to prevent the third conductive portion 12c from being removed.

In step S7, as illustrated in FIG. 3, in the pixel region R1, the flattening film 104 is deposited on the protection film 103.

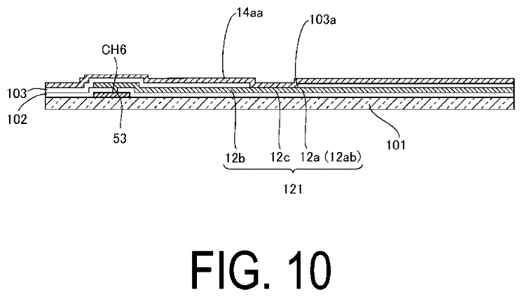

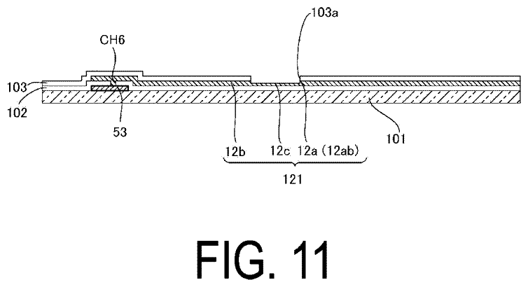

In step S8, in the pixel region R1, the cathode connection electrode 14a and the connection electrode 12d are deposited. As illustrated in FIG. 10, in step S8, in the frame region R2, the conductive layer 14aa is deposited, covering the protection film 103. Note that, in step S8, the connection electrode 12e (refer to FIG. 5), the connection electrode 13e (refer to FIG. 6), the terminal connection electrodes 32a and 32b (refer to FIG. 5), and the terminal connection electrodes 33a and 33b (refer to FIG. 6) are deposited. Then, as illustrated in FIG. 11, the cathode connection electrode 14a, the connection electrode 12d, the conductive layer 14aa, the connection electrode 12e, the connection electrode 13e, the terminal connection electrodes 32a and 32b, and the terminal connection electrodes 33a and 33b are patterned by dry etching. Note that, as for the conductive layer 14aa, the entire conductive layer 14aa is removed. As illustrated in FIG. 11, the third conductive portion 12c remains even after step S8 is executed.

In step S9, the inorganic insulating film 105a is deposited and patterned. Then, in step S10, in the pixel region R1, the cathode 14b (refer to FIG. 3) of the photodiode 14 is deposited on part of the inorganic insulating film 105a and on the cathode connection electrode 14a and patterned. In this step S10, in the frame region R2, the terminal connection electrodes 32c and 33c (refer to FIG. 5 and FIG. 6) are deposited and patterned.

In step S11, in the pixel region R1, the photoelectric conversion layer 16 (refer to FIG. 3) is deposited. Specifically, the n-type amorphous semiconductor layer 161, the intrinsic amorphous semiconductor layer 162, and the p-type amorphous semiconductor layer 163 are sequentially layered. In step S12, in the pixel region R1, the anode 14c is deposited in an upper layer above the p-type amorphous semiconductor layer 163.

In step S13, the inorganic insulating film 105b is deposited and patterned. In step S14, in the pixel region R1, the flattening film 106 is deposited as illustrated in FIG. 3.

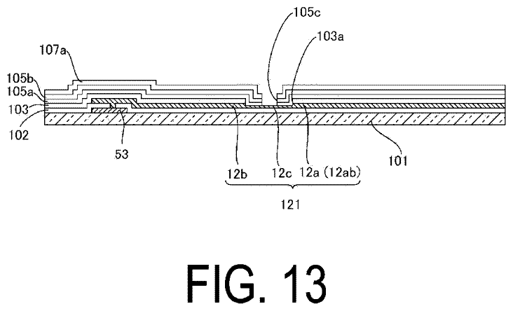

In step S15, the inorganic insulating film 107a is deposited and patterned. In this step S15, as illustrated in FIG. 13, the inorganic insulating film 105a, the inorganic insulating film 105b, and part of a portion of the inorganic insulating film 107a overlapping the third conductive portion 12c in a plan view are removed by dry etching. Note that the third conductive portion 12c is not removed by dry etching, and thus part of the third conductive portion 12c is exposed. As a result, the recessed portion 105c including the third conductive portion 12c as a bottom face is formed.

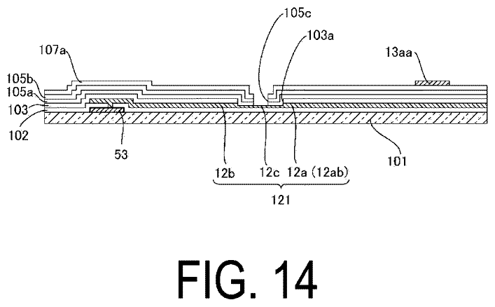

In step S16, the first conductive portion 12aa of the data line 12 and the first conductive portion 13aa of the bias line 13 in the pixel region R1 are deposited and patterned. Note that, as illustrated in FIG. 14, the first conductive portion 13aa of the bias line 13 is also deposited in the frame region R2. When the first conductive portion 13ab of the bias line 13 is patterned, dry etching is performed. Here, because the third conductive portion 12c is not removed by dry etching, the third conductive portion 12c remains as illustrated in FIG. 14. As a result, the third conductive portion 12c remains while all electrodes (conductive layer) of the photoelectric conversion panel 1 are formed, making it possible to disperse the static electricity of the TFT 15 and the photodiode 14 by the short ring 53.

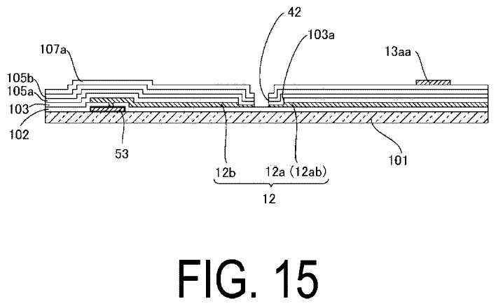

In step S17, as illustrated in FIG. 15, the data line 121 is cut. Specifically, the first conductive portion 12a and the second conductive portion 12b are blocked (divided) from each other by removing the third conductive portion 12c of the data line 121 by wet etching. As a result, the blocking portion 42 is formed. By the blocking portion 42, the first conductive portion 12a and the second conductive portion 12b are electrically blocked from each other, and the short ring 53 and the TFT 15 or the photodiode 14 are electrically blocked from each other. The blocking portion 42 is a recessed portion obtained by removing the third conductive portion 12c of the recessed portion 105c and thus including the gate insulating film 102 as a bottom face. Note that a portion of the first conductive portion 13aa that is not completely etched and remains in step S16 is removed by wet etching in step S17. As a result, it is possible to prevent the occurrence of current leakage caused by the remaining portion.

Then, in step S18, the inorganic insulating film 107b is deposited on the flattening film 106, covering the first conductive portions 12aa and 13aa, and patterned, exposing the terminal connection electrode 32c. As illustrated in FIG. 7, in this step S18, the portion 107c of the inorganic insulating film 107b is formed in the blocking portion 42 (recessed portion). Thus, the first conductive portion 12a and the second conductive portion 12b are blocked from each other by the inorganic insulating film 107b. The first conductive portion 12a and the second conductive portion 12b are covered with the inorganic insulating film 107b, making it possible to prevent exposure of the data line 12.

In step S19, as illustrated in FIG. 4 to FIG. 6, the gate terminal 31, the data terminal 32, and the bias terminal 33 are deposited and patterned. In step S20, the flattening film 108 is deposited and patterned. As a result, the photoelectric conversion panel 1 is completed.

In step S21, the scintillator 2 is disposed covering the pixel region R1. As a result, the X-ray imaging panel 10 is completed. In this state, an imaging inspection of the X-ray imaging panel 10 can be executed.

According to the manufacturing method described above, it is possible to electrically block the short ring 53 and the TFT 15 or the photodiode 14 from each other without arranging components (for example, a fuse and a heater) for cutting the gate line 11, the data line 12, and the bias line 13 in the photoelectric conversion panel 1. As a result, the number of components of the photoelectric conversion panel 1 can be reduced. Further, the arrangement of components for cutting the wiring lines described above is not required, making it possible to reduce the number of manufacturing processes of the photoelectric conversion panel 1.

Further, according to the manufacturing method described above, even after the first conductive portion 12a and the second conductive portion 12b are blocked from each other, the first conductive portion 12a can be utilized as a wiring line for connecting the data terminal 32 and the TFT 15. As a result, the number of components of the photoelectric conversion panel 1 can be reduced as compared with a case in which the wiring line for connecting the data terminal 32 and the TFT 15 is separately provided.

### Modified Examples

Embodiments have been described above, but the embodiments described above are merely examples for implementing the disclosure. Thus, the disclosure is not limited to the embodiments described above and can be implemented by modifying the embodiments described above as appropriate without departing from the scope of the disclosure.

(1) In the embodiment described above, an example is illustrated in which the first conductive portions 11ab, 12ab, and 13ab and the second conductive portions 11b, 12b, and 13b are formed in an upper layer above the layer in which the short ring 53 is formed. However, the disclosure is not limited thereto. That is, the first conductive portions 11ab, 12ab, and 13ab and the second conductive portions 11b, 12b, and 13b may be formed in the same layer as the layer in which the short ring 53 is formed, or in a lower layer below the layer in which the short ring 53 is formed.

(2) In the embodiment described above, an example is illustrated in which the first conductive portion and the second conductive portion are cut by wet etching. However, the disclosure is not limited thereto. For example, the first conductive portion and the second conductive portion may be cut by dry etching, or the first conductive portion and the second conductive portion may be cut with a blade.

(3) In the embodiment described above, an example is illustrated in which the first conductive portion is configured to include a conductive material containing aluminum. However, the disclosure is not limited thereto. For example, the first conductive portion may be made of a conductive material (such as copper, silver, gold, or ITO) that does not contain aluminum.

(4) In the embodiment described above, an example is illustrated in which the first conductive portions 11ab, 12ab, and 13ab are formed in the same layer as the layer in which the source electrode 15c and the drain electrode 15d are formed. However, the disclosure is not limited thereto. That is, the first conductive portions 11ab, 12ab, and 13ab may be formed in an upper layer above or a lower layer below the layer in which the source electrode 15c and the drain electrode 15d are formed.

(5) In the embodiment described above, an example of the materials of the layers (films) constituting the photoelectric conversion panel is illustrated. However, the disclosure is not limited thereto. That is, the layers (films) forming the photoelectric conversion panel may be made of materials not used in the example described above.

The above-described configuration can also be described as follows.

A manufacturing method of a photoelectric conversion panel according to a first configuration includes forming a transistor in a pixel region on a substrate, forming a photodiode connected to the transistor in the pixel region, forming a short ring surrounding the pixel region in a plan view, forming a plurality of wiring lines short-circuited by the short ring and connected to the transistor or the photodiode and the short ring, forming a bias line connected to the photodiode in an upper layer above the photodiode, electrically blocking the short ring and the transistor or the photodiode from each other by cutting the plurality of wiring lines after the forming of the bias line, and forming a first insulating film in a recessed portion created by the plurality of wiring lines being cut (first configuration).

According to the first configuration described above, it is possible to prevent, by the first insulating film, the plurality of wiring lines from being exposed after the plurality of wiring lines are cut. Further, it is possible to electrically block the short ring and the transistor or the photodiode from each other without arranging components (for example, a fuse and a heater) for cutting the wiring lines in the photoelectric conversion panel (X-ray imaging panel). As a result, the number of components of the photoelectric conversion panel (X-ray imaging panel) can be reduced. Further, the arrangement of components for cutting the wiring lines is not required, making it possible to reduce the number of manufacturing processes of the photoelectric conversion panel.

In the first configuration, the forming of the plurality of wiring lines may include forming a conductive layer in an upper layer above the layer in which the short ring is formed, forming a second insulating film covering the conductive layer, and removing a portion of the second insulating film overlapping, in a plan view, a portion of the plurality of wire lines to be cut to expose the conductive layer (second configuration).

According to the second configuration described above, the first insulating portion overlapping the portion of the plurality of wiring lines to be cut in a plan view is removed, making it possible to easily cut the plurality of wiring lines after this process.

In the second configuration, the forming of the conductive layer may include forming the conductive layer from a conductive material including aluminum. The forming of the second insulating film may include forming the second insulating film from an insulating material including silicon dioxide. The forming of the plurality of wiring lines may include, after the forming of the second insulating film, changing at least an exposed portion of the conductive layer into a state including an aluminum-silicon alloy, by thermally treating the exposed portion. The forming of the bias line may include dry etching. The cutting of the plurality of wiring lines may include wet etching (third configuration).

According to the third configuration described above, the aluminum-silicon alloy is not removed by dry etching and thus, even when a part of the plurality of wiring lines is exposed, it is possible to prevent removal by dry etching when the bias line is formed. Then, the aluminum-silicon alloy can be removed by wet etching, making it possible to cut the plurality of wiring lines by wet etching.

In any one of the first to third configurations, the manufacturing method may further include forming a plurality of terminals on the plurality of wiring lines outside the pixel region and inside the short ring. The cutting of the plurality of wiring lines may include cutting a portion of the plurality of wiring lines that connects the plurality of terminals and the short ring (fourth configuration).

According to the fourth configuration described above, a portion of the plurality of wiring lines can be utilized as wiring lines for connecting the transistor or the photodiode even after cutting the plurality of wiring lines. As a result, the number of components of the photoelectric conversion panel can be reduced as compared with a case in which the wiring lines for connecting the plurality of terminals and the transistor or the photodiode are separately provided.

In any one of the first to fourth configurations, the forming of the transistor may include forming a gate electrode, and forming a source electrode or a drain electrode in an upper layer above the gate electrode. The forming of the short ring may include forming the short ring in the same layer as the layer in which the gate electrode is formed. The forming of the plurality of wiring lines may include forming the plurality of wiring lines in the same layer as the layer in which the source electrode or the drain electrode is formed (fifth configuration).

According to the fifth configuration described above, the short ring and the plurality of wiring lines can be formed in the same process as the process of forming the transistor. As a result, the number of manufacturing processes for the photoelectric conversion panel can be reduced.

A photoelectric conversion panel according to a sixth configuration includes a transistor formed in a pixel region on a substrate, a photodiode formed in the pixel region and connected to the transistor, a ring-shaped wiring line surrounding the pixel region in a plan view, a wiring line portion including a first conductive portion connected to the transistor or the photodiode and a second conductive portion connected to the ring-shaped wiring line, the first conductive portion and the second conductive portion being electrically blocked from each other, a bias line formed in an upper layer above the photodiode and connected to the photodiode, and a first insulating film formed in an upper layer above the bias line with at least a portion being formed between the first conductive portion and the second conductive portion, the first insulating film being configured to insulate the first conductive portion and the second conductive portion (sixth configuration).

According to the sixth configuration described above, it is possible to provide a photoelectric conversion panel that facilitates a reduction in the number of components and a reduction in the number of manufacturing processes.

An X-ray imaging panel according to a seventh configuration includes a transistor formed in a pixel region on a substrate, a photodiode formed in the pixel region and connected to the transistor, a ring-shaped wiring line surrounding the pixel region in a plan view, a wiring line portion including a first portion connected to the transistor or the photodiode and a second portion connected to the ring-shaped wiring line, the first portion and the second portion being electrically blocked from each other, a bias line formed in an upper layer above the photodiode and connected to the photodiode, a first insulating film formed in an upper layer above the bias line with at least a portion being formed between the first portion and the second portion, the first insulating film being configured to insulate the first portion and the second portion, and a scintillator covering the pixel region (seventh configuration).

According to the seventh configuration described above, it is possible to provide an X-ray imaging panel that facilitates a reduction in the number of components and a reduction in the number of manufacturing processes.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A manufacturing method of a photoelectric conversion panel, the manufacturing method comprising:
forming a transistor in a pixel region on a substrate;
forming a photodiode connected to the transistor in the pixel region;
forming a short ring surrounding the pixel region in a plan view;
forming a plurality of wiring lines short-circuited by the short ring and connected to the transistor or the photodiode and the short ring;
forming a bias line connected to the photodiode in an upper layer above the photodiode;
electrically blocking the short ring and the transistor or the photodiode from each other by cutting the plurality of wiring lines after the forming of the bias line; and
forming a first insulating film in a recessed portion created by the plurality of wiring lines being cut.

2. The manufacturing method according to claim 1,
wherein the forming of the plurality of wiring lines includes
forming a conductive layer in an upper layer above the layer in which the short ring is formed,
forming a second insulating film covering the conductive layer, and
removing a portion of the second insulating film overlapping, in a plan view, a portion of the plurality of wire lines to be cut to expose the conductive layer.

3. The manufacturing method according to claim 2,
wherein the forming of the conductive layer includes forming the conductive layer from a conductive material including aluminum,
the forming of the second insulating film includes forming the second insulating film from an insulating material including silicon dioxide,
the forming of the plurality of wiring lines includes, after the forming of the second insulating film, changing at least an exposed portion of the conductive layer into a state including an aluminum-silicon alloy, by thermally treating the at least exposed portion,
the forming of the bias line includes dry etching, and
the cutting of the plurality of wiring lines includes wet etching.

4. The manufacturing method according to claim 1, further comprising:
forming a plurality of terminals on the plurality of wiring lines outside the pixel region and inside the short ring,
wherein the cutting of the plurality of wiring lines includes cutting a portion of the plurality of wiring lines that connects the plurality of terminals and the short ring.

5. The manufacturing method according to claim 1,
wherein the forming of the transistor includes
forming a gate electrode, and
forming a source electrode or a drain electrode in an upper layer above the gate electrode,
the forming of the short ring includes forming the short ring in the same layer as the layer in which the gate electrode is formed, and
the forming of the plurality of wiring lines includes forming the plurality of wiring lines in the same layer as the layer in which the source electrode or the drain electrode is formed.

6. A photoelectric conversion panel comprising:
a transistor formed in a pixel region on a substrate;
a photodiode formed in the pixel region and connected to the transistor;
a ring-shaped wiring line surrounding the pixel region in a plan view;
a wiring line portion including
a first conductive portion connected to the transistor or the photodiode, and
a second conductive portion connected to the ring-shaped wiring line,
the first conductive portion and the second conductive portion being electrically blocked from each other;
a bias line formed in an upper layer above the photodiode and connected to the photodiode; and
a first insulating film formed in an upper layer above the bias line with at least a portion being formed between the first conductive portion and the second conductive portion, the first insulating film being configured to insulate the first conductive portion and the second conductive portion.

7. An X-ray imaging panel comprising:
a transistor formed in a pixel region on a substrate;
a photodiode formed in the pixel region and connected to the transistor;
a ring-shaped wiring line surrounding the pixel region in a plan view;
a wiring line portion including
a first portion connected to the transistor or the photodiode, and
a second portion connected to the ring-shaped wiring line,
the first portion and the second portion being electrically blocked from each other;
a bias line formed in an upper layer above the photodiode and connected to the photodiode;
a first insulating film formed in an upper layer above the bias line with at least a portion being formed between the first portion and the second portion, the first insulating film being configured to insulate the first portion and the second portion; and
a scintillator covering the pixel region.
